(19) United States
(12) Patent Application Publication
(10) Pub. No.: US 2015/0216057 A1
(43) Pub. Date: Jul. 30, 2015

(54) METHOD FOR MANUFACTURING FLEXIBLE-EMBEDDED ELECTRODE FILM USING HEAT-PRESSURE WELDING TRANSCRIPTION

(71) Applicant: LG CHEM, LTD., SEOUL (KR)

(72) Inventors: Jeongho Park, Daejeon (KR); Bugon Shin, Daejeon (KR); Jaejin Kim, Daejeon (KR); Jongbyung Lee, Daejeon (KR); Jinmi Jung, Daejeon (KR)

(21) Appl. No.: 14/423,015

(22) PCT Filed: Jul. 24, 2014
(86) PCT No.: PCT/KR2014/006751

§ 371 Date: Feb. 20, 2015

(30) Foreign Application Priority Data
Jul. 30, 2013 (KR) 10-2013-0090393
Jul. 23, 2014 (KR) 10-2014-0093169

(51) Int. Cl. H05K 3/20; B32B 37/00; H05K 1/02

(52) U.S. Cl. CPC H05K 3/20; H05K 1/0284; H05K 1/0296; B32B 37/025; H05K 2201/09036; H05K 2203/06; B32B 2305/38; B32B 2457/08

(57) ABSTRACT

This invention relates to a method of manufacturing a buried flexible electrode film, including 1) preparing a release-substrate; 2) forming a conductive pattern layer on the release-substrate; 3) positioning a transfer-substrate on the conductive pattern layer and then performing thermal and pressure lamination so that the conductive pattern layer formed on the release-substrate is inserted or buried in the surface of the transfer-substrate; and 4) separating the release-substrate and the conductive pattern layer from each other, and to a buried flexible electrode film manufactured thereby.

### BACKGROUND OF THE INVENTION

1. Technical Field

The present invention relates to a method of manufacturing a buried flexible electrode film using thermal lamination transfer.

2. Description of the Related Art

With the recent advancement in the electrical and electronic industries, a variety of home appliances and electronic products have been developed. Due to trend for more compact electronic products, thorough research is ongoing to cope with the technical demands for reducing the size and the thickness of such electronic products.

Circuit boards include circuit wires for electrically connecting electrical devices, electronic devices and semiconductor packages. Although conventional circuit wires may be composed of a metal wiring pattern formed on an insulating board, when the circuit wires on the insulating board are crossed in the same plane, an electrical short may occur between the circuit wires. Hence, the circuit board typically includes multilayer circuit patterns which are electrically insulated.

However, forming the multilayer circuit patterns on a circuit board has to be carried out by a series of complicated processes, and thereby wiring defects may be incurred during the manufacturing process. Also, forming many complicated wires on the board inevitably requires wiring having a smaller line width. As the width of the wiring decreases, the cross-sectional area thereof is reduced, thus causing problems of high resistance, low power efficiency and heat generation. To solve these problems, methods of lowering resistivity, of decreasing the length of wiring or of increasing the height (thickness) of wiring are being devised.

However, considerable effort and time are needed to develop materials having resistivity as low as that of conventionally useful metallic materials such as copper, aluminum or silver.

In existing electrode forming techniques, indium tin oxide (ITO) is very useful. However, indium, mainly contained in ITO, which is a conductive metal oxide, is unsuitable for use in a flexible electrode introduced on a plastic board requiring flexibility due to its high brittleness thereof. Accordingly, to solve problems with electrodes using ITO, manufacturing techniques using carbon nanotubes or conductive polymer materials are under investigation but still remain in the study stages, and thus the development of the manufacturing process necessary for practical product development needs more time.

Designing a resistance circuit via a short wiring length is difficult to actually implement in a variety of electronic devices. Moreover, increasing the height of wiring is difficult in terms of processes, and also involves problems of wire breaking and an electrical short between wires.

Alternatives to resolving such problems include techniques for forming a metal wiring pattern using a burying process. For example, Korean Patent No. 10-0957487 discloses a method of manufacturing a plastic electrode in the form of an electrode circuit being buried in a film, by forming a negative pattern through an imprinting process using a mold having a designed pattern, selectively filling the receding part of the negative pattern with a conductive material, removing the conductive material formed at a portion other than the recess, and performing selective wet plating and depositing with a transparent conductive material over whole area to be used for current spreading layer. However, this technique is complicated due to a plurality of processes including pattern engraving, selective filling of the engraved portion (recess) with the conductive material, and forming the conductive film, and makes it difficult to completely remove the conductive material from the portion other than the engraved portion, and unavoidably creates defects in each of the individual processes.

Also, Korean Patent No. 10-1191865 discloses a method of manufacturing a flexible conductive film, comprising forming a sacrificial layer on a board, forming a metal electrode wiring pattern, applying a curable polymer, and selectively removing the sacrificial layer to peel off the curable polymer layer having the electrode wiring from the board. However, this technique is problematic because of complicated processes with the addition of coating and curing of the curable polymer layer, and wet peeling. Furthermore, in the wet peeling process of the sacrificial layer, the exposure area of the sacrificial layer is small in a lateral direction of the film, and thus the wet dissolution rate may decrease, making it worse to scale up a large-area conductive film.

Therefore, the present inventors have proposed a method of manufacturing a flexible film having a conductive pattern buried therein using a simpler process.

### SUMMARY OF THE INVENTION

Accordingly, the present invention has been made keeping in mind the problems encountered in the prior art, and an object of the present invention is to provide a method of manufacturing a flexible electrode film having a conductive pattern buried therein using a simple process and a buried flexible electrode film manufactured thereby.

In order to accomplish the above object, the present invention provides a method of manufacturing a buried flexible electrode film, comprising: 1) preparing a release-substrate; 2) forming a conductive pattern layer on the release-substrate; 3) positioning a transfer-substrate on the conductive pattern layer and then performing thermal and pressure lamination so that the conductive pattern layer formed on the release-substrate is inserted or buried in the surface of the transfer-substrate; and 4) separating the release-substrate and the conductive pattern layer from each other.

In addition, the present invention provides a buried flexible electrode film, manufactured by the method as above and comprising: a substrate film; an engraved portion or a recess formed on a surface of the substrate film; and a conductive pattern buried in the engraved portion or the recess, wherein the conductive pattern has an interconnected mesh shape.

According to the present invention, a method of manufacturing a buried flexible electrode film enables a fine conductive pattern to be inserted or buried in a plastic film, thus easily forming wiring having low resistance without the height limitations of metal wiring.

In the method of manufacturing a buried flexible electrode film according to the present invention, a transfer process is performed using thermal and pressure lamination, thus achieving a simple process and effectively manufacturing a large-area plastic electrode film.

According to the present invention, a buried flexible electrode film is configured such that a fine conductive pattern is embedded or buried in a plastic film, thus preventing problems in which the pattern may break or may short-out depending on an increase in the aspect ratio of the fine pattern, resulting in excellent durability. Furthermore, superior adhesion can be exhibited, and surface contamination with residue of conducting materials in the film is minimized, thereby manifesting high transmittance and a superior resistance value and completely eliminating the generation of a level difference between the conductive layer and the substrate. Therefore, the electrode film of the invention can be usefully employed in electrode boards for flexible displays and touch panels, assistant electrodes of transparent boards for displays, negative electrode plates for solar cells, and flexible printed circuit boards (FPCBs).

### BRIEF DESCRIPTION OF THE DRAWINGS

FIG. 1 schematically illustrates a process of manufacturing a buried flexible electrode film according to the present invention;

FIG. 2 illustrates optical microscope images of an Al pattern remaining on a release-substrate after an etching process in Example 1;

FIG. 3 illustrates optical microscope images of a buried electrode film finally manufactured in Example 1;

FIG. 4 illustrates electron microscope images of the buried electrode film finally manufactured in Example 1;

FIG. 5 illustrates a total image and a close-up image of the buried electrode film finally manufactured in Example 1;

FIG. 6 illustrates electron microscope images of a buried electrode film manufactured by a solution process using a silver nanoparticle solution in Comparative Example 1 (a mesh pattern having a line width of 1.5 μm, a height of 1 μm and a grid spacing of 40 μm);

FIG. 7 illustrates electron microscope images showing a level difference in the protrusion of the pattern after filling of the engraved portion of the silver pattern with nanoparticles in Comparative Example 1 (a mesh pattern having a line width of 5 μm a height of 0.5 μm and a grid spacing of 300 μm); and

FIG. 8 illustrates an optical microscope image and an electron microscope image showing the undesired conductive residue on the protrusion of the pattern in a conductive pattern resulting from selective filling of the engraved portion with silver nanoparticles using a solution process in Comparative Example 1 ((left) a mesh pattern having a line width of 1.5 μm, a height of 1 μm and a grid spacing of 40 μm; (right) a mesh pattern having a line width of 5 μm a height of 0.5 μm and a grid spacing of 300 μm).

### DESCRIPTION OF THE SPECIFIC EMBODIMENTS

Hereinafter, a detailed description will be given of the present invention.

The present invention addresses a method of manufacturing a buried flexible electrode film, comprising: 1) preparing a release-substrate; 2) forming a conductive pattern layer on the release-substrate; 3) positioning a transfer-substrate on the conductive pattern layer and then performing thermal and pressure lamination so that the conductive pattern layer formed on the release-substrate is inserted or buried in the surface of the transfer-substrate; and 4) separating the release-substrate and the conductive pattern layer from each other.

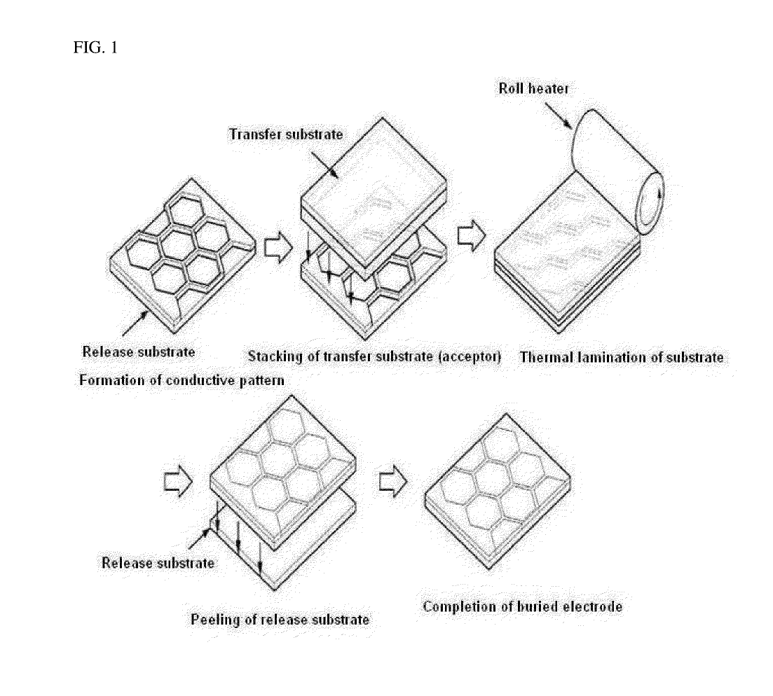

The method of manufacturing the buried flexible electrode film according to the present invention is schematically illustrated in FIG. 1.

The release-substrate may be a substrate having releasability, or a base substrate coated with a release agent.

The base substrate is not particularly limited but may include a glass substrate, a plastic substrate such as polyethylene terephthalate (PET), polysulfone (PSF), polyethersulfone (PES), polycarbonate (PC), polyimide (PI) or cyclo olefin polymer (COP), and a metal substrate such as an STS board, an aluminum board or a copper board.

The thickness of the base substrate is not particularly limited but is preferably set to 40˜400 μm taking into consideration the manufacturing properties of a roll-to-roll-based continuous process.

The release agent imparts the release-substrate with releasability, that is, causes the release-substrate to have an interface having moderately low surface energy, so as to enable the separation of the release-substrate and the conductive pattern formed on the release-substrate in subsequent step 4). The release agent may include a polymer material and a monomer material, and preferably includes a polymer material including a silicon-based compound such as polydimethylsiloxane (PDMS) derivative, an n-alkyl compound (a saturated alkyl compound), a fluorine-based compound such as perfluoropolyether (PFPE) or Teflon (polytetrafluoroethylene: PTFE). When the release agent comprising the polymer material is used, the release agent may function alone as a base substrate. As such, the thickness of the release agent functioning as the base substrate has no relation with the thickness of the base substrate.

In addition to the release agent comprising the polymer material, useful as the monomeric material is a silane-based fluorine compound for surface modification, for example, perfluoroalkylsilane, partial fluoroalkylsilane or a silane-based hydrocarbon compound (alkyl or alkoxy silane) so that the surface of the board may be imparted with releasability by decreasing the surface energy of the board. This is because a hydroxyl group (—OH) which is naturally present or intentionally introduced on the surface of the substrate is reacted with a silane group (R−Si−X₃, R=fluorine compound, alkyl group, X=compound substituted with any one of alkyl group, alkoxy group and halide) and thus the surface of the substrate is fluorinated and hydrocarbonized to thereby decrease the surface energy of the board to impart releasability.

The polymer release agent requires processes such as coating, curing or drying, and the monomer release agent needs coating and drying, with intentional introduction of a hydroxyl group to the surface of the substrate through coating with an oxide film, UV ozone treatment or oxygen plasma treatment when the substrate has no hydroxyl group, in order to impart superior releasability.

The release agent is not limited to the kinds of materials listed as above, and may be appropriately selected depending on the process properties and the release properties (or peel strength).

Coating the base substrate with the release agent may be performed using a coating process such as spin coating, bar coating, roll coating or spray coating regardless of the kind of polymer release agent or silane-based compound for surface treatment, and drying and curing the release agent may be performed using hot air drying at 50˜150° C. As such, the drying time may vary depending on the amount of air but is preferably set to 1 min˜8 hr.

When the base substrate is coated with the release agent, the coating thickness is adjusted considering the peel strength with the conductive pattern layer.

When the release layer is too thin, uniform contact between the release-substrate and the target plastic board becomes difficult and thus complete pattern transfer does not occur on the overall area and a portion where no pattern transfer occurs may be formed on the local area. In contrast, when the release layer of the release-substrate is too thick, there may occur a thickness variation of the plastic film having a conductive pattern layer buried therein after a transfer process depending on the applied pressure and temperature, or the conductive pattern is not uniformly buried in the top of the plastic substrate but the transferred pattern is partially buried or completely inserted in a portion of the entire film, and thus the degree of burying the pattern may become different depending on the position of the substrate, undesirably resulting in a non-uniform flatness.

When using the polymer release agent, a coating process is preferably performed so as to form a film having a thickness of 0.01˜10 mm. If the thickness falls out of the above range, uniformity of the transferred pattern may decrease.

In the melt transfer process of the target board, the release layer having a predetermined thickness plays a role in aiding uniform contact between the release-substrate including the conductive pattern layer and the target plastic board. Useful as the release layer is a polymer layer composed of polydimethylsiloxane or perfluoropolyether having a low Young's modulus.

In a preferred embodiment of the present invention, a PET board is spin-coated with polydimethylsiloxane.

In step 2), the conductive pattern layer is formed on the release-substrate having releasability as above.

The conductive pattern layer may include a metal, such as silver (Ag), copper (Cu), aluminum (Al), gold (Au), nickel (Ni), titanium (Ti), molybdenum (Mo), tungsten (W), chromium (Cr) or platinum (Pt), or alloys thereof, and may include oxides and metal mixed electrode materials, such as indium tin oxide (ITO), indium zinc oxide (IZO), aluminum zinc oxide (AZO), indium zinc tin oxide (IZTO), aluminum zinc oxide-silver-aluminum zinc oxide (AZO-Ag-AZO), indium zinc oxide-silver-indium zinc oxide (IZO-Ag-IZO), indium tin oxide-silver-indium tin oxide (ITO-Ag-ITO), or indium zinc tin oxide-silver-indium zinc tin oxide (IZTO-Ag-IZTO).

The process of forming the conductive pattern layer may include, but is not necessarily limited to, for example, printing such as photolithography, inkjet, gravure, imprinting or offset, electroplating, vacuum deposition, thermal deposition, sputtering, and e-beam deposition.

The line width of the conductive pattern layer is not particularly limited, but may be 50 nm˜20 μm.

Also, the thickness (height) of the conductive pattern layer is not particularly limited, but may be 5 nm˜5 μm.

The thickness (height) of the conductive pattern layer may vary depending on the line width of the pattern and the electrical properties (conductivity and resistivity) of applied devices.

The buried flexible electrode film according to the present invention is an electrode structure which has high effectiveness with a reduction in the line width. Briefly, depending on the aspect ratio of the pattern, namely, the line width to height ratio of the pattern, a difficulty of the manufacturing process is determined. However, the effect of the aspect ratio of the pattern on the difficulty of the manufacturing process may depend on the pattern structure.

The pattern structure may have an interconnected mesh shape or may be made of separate and independent single lines or wiring made of such lines. In the present invention, the pattern structure preferably has an interconnected mesh shape.

As for the conductive wiring having an interconnected mesh shape, even when the aspect ratio of the transferred pattern is as slightly high as 2 or more, the conductive pattern layer is interconnected, thus minimizing distortion of the finally transferred and buried pattern through the optimization of a melt transfer process in consideration of uniform contact between a target substrate and a substrate including a metal, a metal oxide and a release agent, surface melting of the target substrate and thermal stress due to a difference in coefficient of thermal expansion between the layers.

On the other hand, when the pattern structure comprising separately and disconnected single lines or wiring made of such lines has an aspect ratio of 2 or more, the conductive pattern on the release layer upon melt transfer may be buried in the target substrate at an inclined angle.

Particularly, unlike parallel contacting, pressing and heating of flat substrates as in the typical nano imprinting process, a thermal lamination transfer process using a roll imprinting-based continuous process as in the present invention may minimize inclined burying of the pattern of the conductive wiring at a predetermined gradient depending on the aspect ratio of the pattern, thanks to the formation of the conductive pattern having an interconnected mesh shape.

When the conductive pattern layer is formed on the release-substrate, in order to peel-off or remove the release-substrate from the transfer-substrate in subsequent step 4), peel strength between the release-substrate and the conductive pattern layer may be dominated by various factors including the structural geometry and thickness of the conductive pattern layer, the temperature and pressure of the transfer process, and properties of the target substrate.

Specifically, the peel strength between the release-substrate and the conductive pattern layer is regarded as key parameter in the manufacturing process, but it may strongly depends on the process of forming the conductive pattern on the release-substrate.

Although the process of forming the conductive pattern is not limited in the present invention, when performing a direct printing process of the conductive pattern on the release-substrate using a solution processable conductive paste or an organic metal derivative and nanoparticle-dispersed ink, the effect of the peel strength on the manufacturing process is not significant.

However, when a resist pattern is formed on a metal film on the release-substrate by deposition and the conductive pattern is formed using an etching process, a dry etching process has no great influence on the processes even when peel strength is low, but a wet etching process may cause the pattern to be peeled off during the etching process. Hence, the peel strength of a predetermined value or more is required. Actually, dry etching needs an expensive equipment such as a vacuum machine and thus effectiveness of wet etching is higher taking into consideration the economically favorable manufacturing process. Thus, the wet etching process requires a minimum adhesive strength between the release layer and the conductive pattern to the extent of not causing peeling of the pattern.

When PDMS is used as the release agent, a peel strength of about 320 N/m is exhibited upon no treatment. Further, when a material such as stearic acid which does not participate in a PDMS curing reaction is added in an amount of about 1 wt %, a peel strength lowered by about 60% (200 N/m) may result. This is considered to be because the concentration of unreacted PDMS residue of the surface of the PDMS film increases due to the presence of stearic acid.

Also, the curing time of the PDMS release layer may be adjusted to thus modify surface properties of the interface of the PDMS release layer, thereby controlling the peel strength.

In order to enhance the peel strength of the PDMS release layer, UV ozone treatment or atmospheric oxygen plasma treatment may be carried out on the surface of PDMS, and thereby the peel strength may be enhanced by maximum 200% or more.

In a preferred embodiment of the present invention, the transfer process was performed as desired when the peel strength was 300˜500 N/m. If the peel strength is less than 300 N/m, the pattern is partially peeled off upon wet etching. In contrast, if the peel strength exceeds 500 N/m, a portion of the pattern may be left behind after a transfer process.

In an embodiment of the present invention, upon transferring the conductive pattern using a roll-to-roll process, a protective film may be further provided on the release layer including the conductive pattern to prevent the pollution of the pattern and to protect the pattern. The peel strength of the protective film is preferably lower than peel strength between the conductive pattern and the release-substrate.

In the present invention, peel strength testing was executed by forming a test sample comprising a PDMS release film (60 μm) and an Al foil (40 μm) which were stacked and cured, peeling the layered film from the test sample at 180° and measuring the force per unit width of the film. To this end, Lloyd instrument 1000 tensometer was used as the measurement device, and measurement was performed at a release rate of 50 mm/min using a load cell of 500 N. Although the thicknesses of the actually useful PDMS release film and Al foil may be slightly different from the thickness of the test sample to be measured, the peel strength was measured with the aforementioned standards for experimental convenience so as to quantify the peel strength at the interface between PDMS and Al. More specifically, a test sample having a width of 30 mm and a minimum length of 100 mm was manufactured for testing, and the peel strength was measured in the 75 mm peeling testing except for the initial 25 mm peeling.

In step 3), the release-substrate and the transfer-substrate are stacked by means of thermal and pressure lamination, thereby transferring the conductive pattern layer to the surface of the transfer-substrate from the release-substrate.

In step 3), the transfer-substrate is preferably a plastic substrate.

The plastic substrate may include at least one selected from among polyethylene terephthalate (PET), polyethylene sulfone (PES), polyethylene naphthalate (PEN), polycarbonate (PC), polymethylmethacrylate (PMMA), polyimide (PI), ethylenevinylacetate (EVA), amorphous polyethylene terephthalate (APET), polypropylene terephthalate (PPT), polyethylene terephthalate glycerol (PETG), polycyclohexylene dimethylene terephthalate (PCTG), modified triacetylcellulose (TAC), cyclo olefin polymer (COP), cyclo olefin copolymer (COC), dicyclopentadiene polymer (DCPD), cyclopentadiene polymer (CPD), polyarylate (PAR), polyetherimide (PEI), polydimethylsiloxane (PDMS), silicone resin, fluorine resin, and modified epoxy resin.

After the transfer process, the transfer-substrate is separated from the release-substrate and then cured using a curing process such as thermal curing, UV curing, microwave curing or IR curing so as to be adapted for the properties of the polymer.

In an embodiment of the present invention, when the transfer-substrate includes a thermoplastic resin, UV is applied to increase curability of the transfer-substrate.

In step 3), thermal and pressure lamination is carried out to stack the release-substrate having the conductive pattern layer and the transfer-substrate.

More specifically, in step 3), the release-substrate and the transfer-substrate are stacked by means of thermal and pressure lamination, the transfer-substrate at a thickness corresponding to ones of micrometers from the surface of the transfer-substrate is melted, and the empty space in the conductive pattern on the release-substrate is filled with the melted transfer-substrate, and thereby the conductive pattern layer is inserted or buried in the surface of the transfer-substrate.

The thermal and pressure lamination conditions may vary depending on the kind of plastic substrate, but preferably include 80˜300° C. and 1˜100 mm/s.

Although these conditions are limitedly disclosed in preferred embodiments, they may be described below based on the thermal properties and the heat transfer properties of the plastic substrate. As for a typical thermoplastic polymer, processing of the polymer is performed at a temperature higher by about 100˜200° C. than a glass transition temperature (Tg) of the polymer, and the melting temperature of the surface of the polymer may vary depending on the kind and thickness of the polymer film and the interfacial energy but is slightly low compared to the melting properties of the polymer bulk, making it possible to carry out the surface melt transfer at a temperature lower than the typical polymer processing temperature. As for a transparent polymer substrate, the properties of the polymer film may deteriorate at 200° C. or higher due to the addition of a plasticizer or a drawing process involved in the manufacturing process. Hence, the aforementioned conditions upon melt transfer are preferable.

In another embodiment of the present invention, preheating the target substrate at a slightly low temperature is additionally conducted and thus the transfer rate is increased, thus increasing the process efficiency and decreasing the transfer temperature, thereby minimizing changes in the inherent physical properties of the film.

The thermal and pressure lamination process is not particularly limited, but in a preferred embodiment of the present invention, thermal lamination is carried out using a cylindrical roll. Ultimately, the conductive pattern formed on the release-substrate is transferred so as to be inserted or buried in the surface of the transfer-substrate by the thermal and pressure lamination with the transfer-substrate.

Step 4) is a process of peeling or removing the release-substrate from the transfer-substrate having the conductive pattern layer inserted or buried therein.

To this end, the peel strength between the release-substrate and the conductive pattern is appropriately controlled by adjusting the component and amount of the release agent and the component and density (filing fraction) of the conductive pattern.

Thus, the process of separating the release-substrate is not particularly limited and any physical process may be applied.

In an embodiment of the present invention, when a planar stacked geometry is subjected to thermal lamination and then peeling-off, the seam thereof is slightly blown using a nitrogen gun, thus easily peeling the release-substrate and the target board due to low surface energy therebetween. In a typical continuous process using a roll-to-roll process, the release-substrate and the conductive pattern-buried substrate roll pass are separated from each other, and thus release may be physically carried out.

In another embodiment of the present invention, in order to completely separate the release-substrate and the conductive pattern layer from each other, a sacrificial layer may be further formed on the release-substrate before step 2).

The sacrificial layer may include a polymer, polymethylmethacrylate (PMMA) or a photoresist (PR) soluble in water or an aqueous alcohol solvent such as polyvinylalcohol, polyvinylpyrrolidone, polyethylene glycol or carboxymethylcellulose, and a polymer soluble in an organic solvent such as acetone, ethyl acetate, methanol, ethanol, chloroform, dichloromethane, hexane, benzene or diethylether to thus be easily removable using the organic solvent. Furthermore, the sacrificial layer may include a photodegradable polymer such as polycaprolactone or polylactic acid.

When the sacrificial layer is formed on the release-substrate, step 4) may include removing only the sacrificial layer by being dissolving in water or an organic solvent or by photodegradation.

In order to minimize the potential of damaging the flexible board during removal of the sacrificial layer, the organic solvent may include, but is not limited to, a lower alcohol such as methanol or ethanol.

In the method of manufacturing the buried flexible electrode film according to the present invention, when the transfer-substrate includes a thermoplastic resin, curing the buried conductive film may be further performed through UV irradiation or additional thermal treatment in the presence of a curing agent added to increase curability of the transfer-substrate, after separation of the release-substrate in step 4).

In the method of manufacturing the buried flexible electrode film according to the present invention, as the transfer process using the thermal and pressure lamination as mentioned above is applied, the process may become simpler in that a conductive pattern is formed on a substrate having controlled releasability and insertion and burying of the pattern are induced through physical thermal lamination on the target substrate, thus allowing for very effective fabrication of a large-area plastic electrode film, compared to existing techniques including a variety of processes such as pattern engraving, selective filling of the engraved portion (recess) with a conductive material, and formation of a conductive film.

In existing processes, it is very difficult to selectively fill only the engraved portion or the recess of the pattern with a conductive material upon production of a buried electrode film. Also, processing the recess of the pattern through selective filling with a conductive material so as to be flush on the protrusion of the pattern is very difficult, even by a solution process using conductive particles and vacuum deposition of a metal film upon formation of a conductive film.

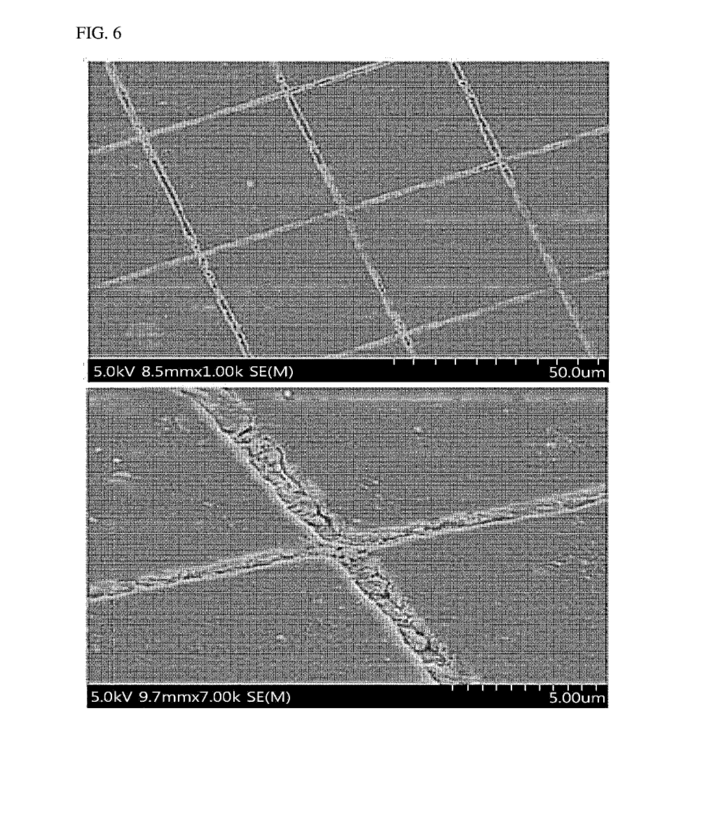

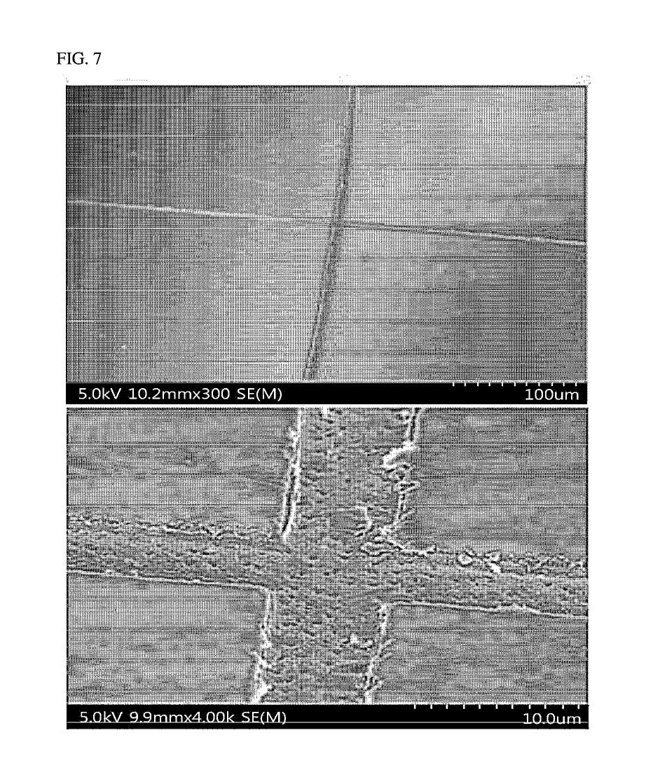

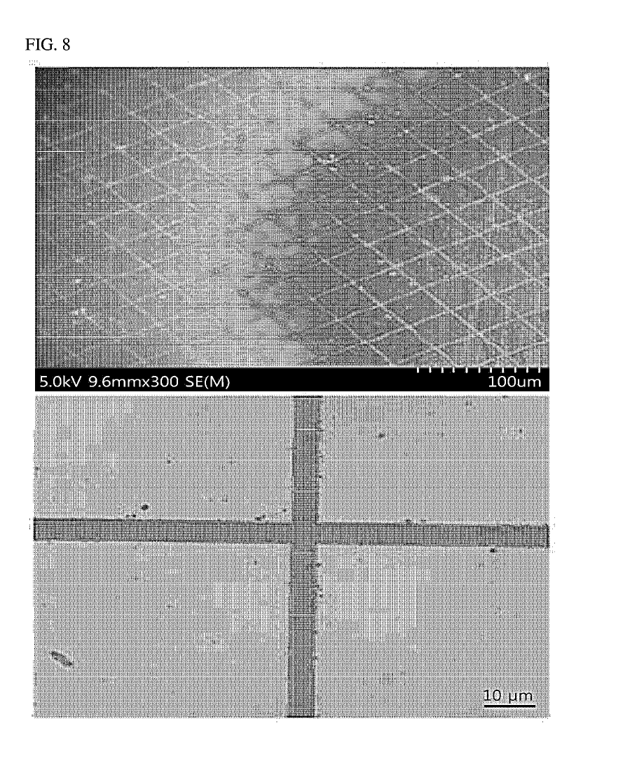

In Comparative Example 1, when a buried electrode is manufactured through selective filling of the recess of the pattern with a solution of silver (Ag) nanoparticles (average particle size ˜50 nm, available from ANP Co. Ltd.), it is difficult to achieve uniform filling with the conductive solution even at a low aspect ratio of 0.1 of the pattern (FIG. 6), and a level difference inevitably occurs between the protrusion and the charged conductive film due to volume shrinkage by the volatilization of the solvent after drying (FIG. 7). Such a level difference may further increase when performing a sintering process to enhance the electrical conductivity. As illustrated in FIG. 8, when a conductive material or film residue may be left behind on an undesired area, namely, the protrusion of the pattern, in terms of transparent electrode in the display application such as touch sensor, a visibility may be poor, thus causing the product quality to deteriorate (FIG. 8). Also in a vacuum deposition process, selective filling is technically difficult, and may be performed in such a manner that the totally deposited film is polished so that the conductive layer of the protrusion is ground, but this process may cause the residue to be left behind, undesirably incurring defective products and making it difficult to control the protrusion to be flush with the conductive layer.

The level difference between the protrusion of the pattern and the recess formed with the conductive layer may incur various problems in most of devices using conductive pattern-based assistant electrodes and transparent electrodes as upper and lower electrodes. These problems may be generated variously depending on the manufacturing process of products and the structure and operating principle thereof. Briefly, for a current driving device, poor driving may be caused by an electrical short in a direction perpendicular to the device, and for a sensor product through changes in capacitance and voltage driving, when a dielectric material is inserted between the upper and lower electrodes, air bubble may be created in the recess of the conductive layer by the formation of an air layer due to a level difference. This makes it impossible to correct the capacitance depending on the position of the conductive film, and mainly causes the visibility of a display to deteriorate.

The present invention addresses a buried flexible electrode film which is manufactured by the aforementioned method and in which a conductive pattern is buried in the flexible plastic substrate.

More specifically, the present invention addresses a buried flexible electrode film, comprising: a substrate film; an engraved portion or a recess formed on a surface of the substrate film; and a conductive pattern buried in the engraved portion or the recess, wherein the conductive pattern has an interconnected mesh shape.

As used herein, the “buried” electrode film refers to an electrode film configured such that the engraved portion or the negatively patterned recess formed on the surface of the substrate film is filled with a conductive pattern material.

The substrate film is preferably a plastic substrate, and may include at least one selected from among polyethylene terephthalate (PET), polyethylene sulfone (PES), polyethylene naphthalate (PEN), polycarbonate (PC), polymethylmethacrylate (PMMA), polyimide (PI), ethylenevinylacetate (EVA), amorphous polyethylene terephthalate (APET), polypropylene terephthalate (PPT), polyethylene terephthalate glycerol (PETG), polycyclohexylene dimethylene terephthalate (PCTG), modified triacetylcellulose (TAC), cyclo olefin polymer (COP), cyclo olefin copolymer (COC), dicyclopentadiene polymer (DCPD), cyclopentadiene polymer (CPD), polyarylate (PAR), polyetherimide (PEI), polydimethylsiloxane (PDMS), silicone resin, fluorine resin, and modified epoxy resin.

The conductive pattern may include a metal such as silver (Ag), copper (Cu), aluminum (Al), gold (Au), nickel (Ni), titanium (Ti), molybdenum (Mo), tungsten (W), chromium (Cr) or platinum (Pt) or alloys thereof, and may include oxides and metal mixed electrode materials, such as indium tin oxide (ITO), indium zinc oxide (IZO), aluminum zinc oxide (AZO), indium zinc tin oxide (IZTO), aluminum zinc oxide-silver-aluminum zinc oxide (AZO-Ag-AZO), indium zinc oxide-silver-indium zinc oxide (IZO-Ag-IZO), indium tin oxide-silver-indium tin oxide (ITO-Ag-ITO), or indium zinc tin oxide-silver-indium zinc tin oxide (IZTO-Ag-IZTO).

The line width of the conductive pattern is not particularly limited, but may be 50 nm˜20 μm.

The thickness (height) of the conductive pattern is not particularly limited, but may be 5 nm˜5 μm.

As for the conductive pattern having a narrow line width, problems of high resistance, low power efficiency and heat generation may occur. With the goal of conventionally solving such problems, attempts have been made to increase the thickness of the conductive pattern, but the problem of breaking the pattern may result.

The buried flexible electrode film according to the present invention is configured such that a fine conductive pattern is buried in the recess formed on a surface of the plastic substrate film, and thereby problems in which the pattern may break or may short-out depending on an increase in the aspect ratio of the fine pattern do not occur, thus manifesting excellent durability.

Therefore, the buried flexible electrode film according to the present invention is very favorable when forming a fine pattern having a high aspect ratio.

Also, the buried flexible electrode film according to the present invention is configured such that a fine conductive pattern is embedded or buried in a plastic film, thus exhibiting high adhesion and no electrical short of an electrode circuit and minimizing the surface pollution of the film, thereby resulting in a high transmittance and a superior resistance value. The electrode film of the invention can be usefully employed in electrode boards for flexible displays and touch panels, assistant electrodes of transparent boards for displays, negative electrode plates for solar cells, and FPCBs.

A better understanding of the present invention may be obtained via the following examples which are set forth to illustrate, but are not to be construed as limiting the scope of the present invention.

### EXAMPLE 1

A PET substrate having a thickness of 180 μm was coated with a 5 mm thick polydimethylsiloxane (PDMS) (SYLGARD 184, available from Dow Corning Corp.) solution (mixing ratio 1:9) and cured at 70° C. for 6 hr, thus preparing a release-substrate. A 150 nm thick Al foil was deposited on the release surface of the release-substrate using an e-beam deposition machine (base pressure: 8×10⁻⁷ torr, working pressure: 5×10⁻⁵ torr, 0.1 Å/s).

Using an AZ 1518 photoresist, coating, drying, mask photoexposure and development were performed, thus forming a pattern on the Al deposited film.

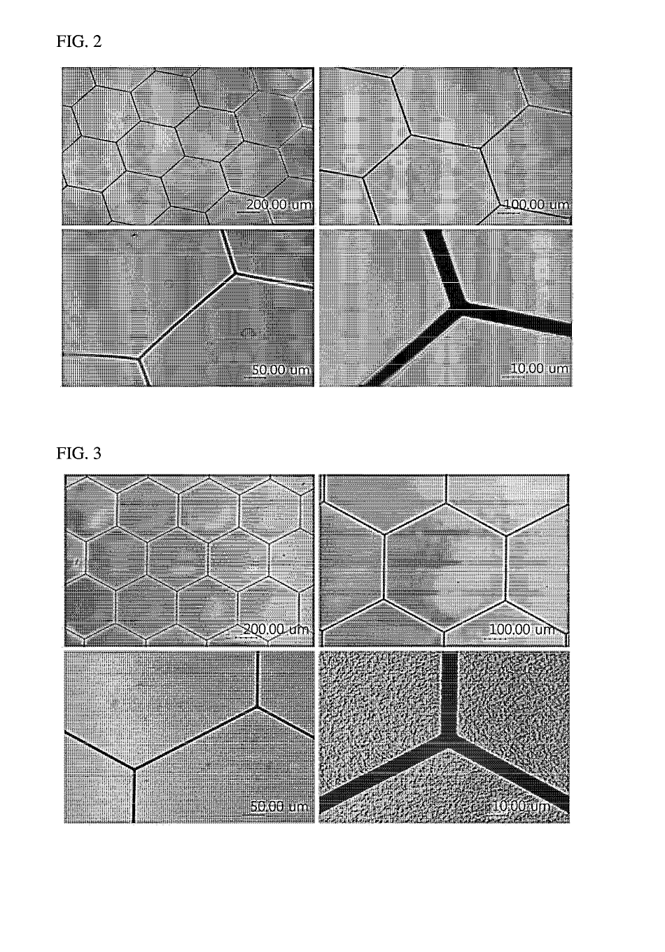

The formed resist pattern was subjected to wet etching (a phosphoric acid-based Al etching solution) or dry etching (ICP-RIE), thus forming an Al electrode pattern. Based on observation by an optical microscope, the Al electrode pattern was formed as illustrated in FIG. 2.

On the Al electrode pattern, a 250 μm EVA (Ethylene Vinyl Acetate) film (Pouch laminating film, available from GMP Ltd.) was positioned and then subjected to thermal lamination under conditions of a stacking temperature of 130° C. and a stacking rate of 2 mm/s.

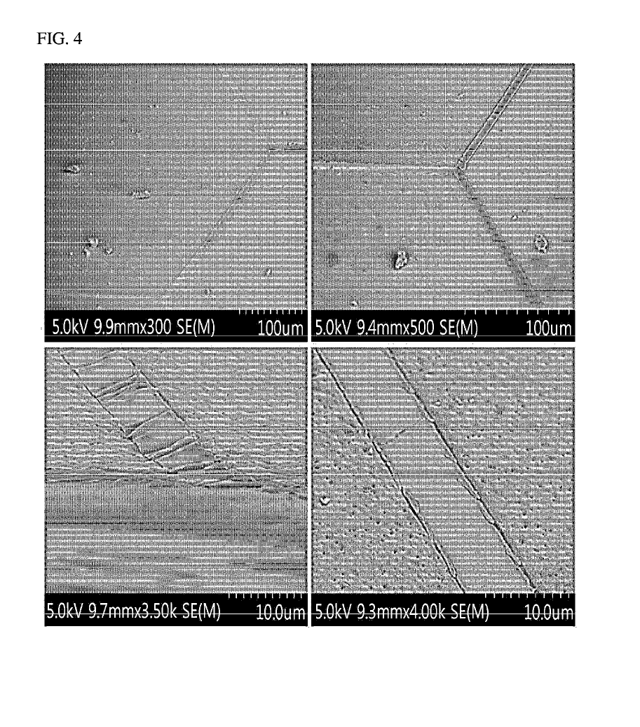

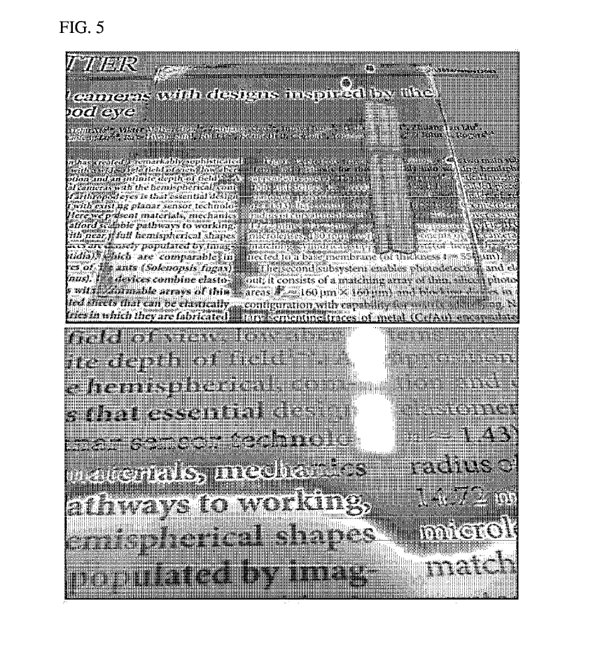

Subsequently, the release-substrate was peeled or removed, thus manufacturing a flexible conductive buried electrode film having a conductive pattern inserted or buried therein. This electrode film was observed by an optical microscope and an electron microscope. The results are illustrated in FIGS. 3 and 4.

### EXAMPLE 2

A flexible conductive buried electrode film was manufactured in the same manner as in Example 1, with the exception that a 180 μm thick PET substrate was spin-coated with a 1˜5 wt % diluted fluorinated silane (OPTOOL™, available from Daikin Industries, LTD.) solution and dried at 120° C. for 30 min, thus preparing a release-substrate.

### COMPARATIVE EXAMPLE 1

Using a photolithography process and a dry etching process, manufactured were pattern master molds made of quartz with a mesh pattern having a line width of 1.5 μm, a height of 1 μm and a grid spacing of 40 μm (FIG. 6) and a mesh pattern (FIG. 7) having a line width of 5 μm, a height of 0.5 μm and a grid spacing of 300 μm. The quartz pattern substrate was spin-coated with a 1˜5 wt % diluted fluorinated silane (OPTOOL™, available from Daikin Industries, LTD.) solution and dried at 120° C. for 30 min so as for release treatment, and UV curing PUA (Poly Urethane Acrylate) (SRM04, available from Minuta Technology Co. Ltd.) was applied on the pattern surface using a spin coating process (500 rpm, 30 sec), and a 180 μm thick PET substrate was stacked, followed by UV irradiation (100 W cm⁻², 120 sec) to perform curing and release, thereby replicating the pattern. Further, a solution of Ag nanoparticles (average particle size ˜50 nm or less, available from ANP Co. Ltd.) was dispensed on the pattern surface, and the Ag nanoparticle residue was minimized on the protrusion of the pattern in such a manner that the nanoparticle solution was squeegeed using a Teflon bar. Furthermore, the recess of the pattern was selectively filled, and dried at 120° C. for 10 min, thereby manufacturing a buried electrode.

What is claimed is:

1. A method of manufacturing a buried flexible electrode film, comprising:
1) preparing a release-substrate;
2) forming a conductive pattern layer on the release-substrate;
3) positioning a transfer-substrate on the conductive pattern layer and then performing thermal and pressure lamination so that the conductive pattern layer formed on the release-substrate is inserted or buried in a surface of the transfer-substrate; and
4) separating the release-substrate and the conductive pattern layer from each other.

2. The method of claim 1, wherein the release-substrate is a base substrate coated with a release agent.

3. The method of claim 2, wherein the base substrate has a thickness of 40˜400 μm.

4. The method of claim 2, wherein the release agent comprises a polydimethylsiloxane derivative, an n-alkyl compound or a fluorine-based compound.

5. The method of claim 2, wherein when the release agent is a polymer release agent, it is applied so as to form a film having a thickness of 0.1˜10 mm.

6. The method of claim 1, wherein in 2), the conductive pattern layer has a line width of 50 nm˜20 μm.

7. The method of claim 1, wherein in 2), the conductive pattern layer has a thickness of 5 nm˜5 μm.

8. The method of claim 1, wherein in 2), the conductive pattern layer has an interconnected mesh shape.

9. The method of claim 1, wherein in 3), the transfer-substrate is a plastic substrate.

10. The method of claim 1, wherein in 3), the thermal and pressure lamination is performed under conditions of 80˜300° C. and 1˜100 mm/s.

11. The method of claim 1, further comprising forming a sacrificial layer on the release-substrate, before 2).

12. The method of claim 1, wherein when the transfer-substrate comprises a thermoplastic resin, applying UV light is further performed after separating the release-substrate in 4).

13. A buried flexible electrode film, manufactured by the method of claim 1 and comprising:
a substrate film;
an engraved portion or a recess formed on a surface of the substrate film; and
a conductive pattern buried in the engraved portion or the recess,
wherein the conductive pattern has an interconnected mesh shape.

14. The buried flexible electrode film of claim 13, wherein the conductive pattern has a line width of 50 nm˜20 μm.

15. The buried flexible electrode film of claim 13, wherein the conductive pattern has a thickness of 5 nm˜5 μm.
